(19) United States
(12) Patent Application Publication
(10) Pub. No.: US 2009/0001532 A1
(43) Pub. Date: Jan. 1, 2009

(54) Plastic-Encapsulated Semiconductor Device with an Exposed Radiator at the Top and Manufacture Thereof

(75) Inventor: Arata Shiomi, Saitama (JP)

Correspondence Address: BACHMAN & LAPOINTE, P.C., 900 CHAPEL STREET, SUITE 1201, NEW HAVEN, CT, 06510, US

(73) Assignee: SANKEN ELECTRIC CO., LTD., Saitama (JP)

(21) Appl. No.: 12/160,111

(22) PCT Filed: Dec. 27, 2006
(86) PCT No.: PCT/JP2006/326012

§ 371 Date: Jul. 7, 2008

(30) Foreign Application Priority Data
Jan. 10, 2006 (JP) 2006-002857

(51) Int. Cl. H01L 23/495; H01L 21/56

(52) U.S. Cl. 257/675; 438/122; 257/E23.051; 257/E21.502

(57) ABSTRACT

A plastic-encapsulated semiconductor device is provided which comprises a plastic-encapsulant 4 formed with notches 14 for exposing outside an upper electrode 12a on a semiconducting element 2 and an inner end 13 of a lead terminal 3a, and a radiator 5 formed with a main radiator body 15 mounted on an upper surface 4a of plastic-encapsulant 4, and connections 16 in notches 14 for electrically connecting upper electrode 12a of semiconducting element 2 with lead terminal 3a through main radiator body 15. Alteration in shape of main radiator body 15 allows appropriate change in thermal volume of radiator 5 by adopting radiator 5 of different shape or size. Also, connections 16 may provide a current path to lead terminal 3a in an existing lead frame without need of change in shape of outer leads 3.

### TECHNICAL FIELD IN INDUSTRY

This invention relates to a plastic-encapsulated semiconductor device having its improved radiation performance and manufacture thereof by providing a specific structure of sandwiching a semiconducting element between a pair of radiators.

### PRIOR ART

FIG. 11 shows a MOSFET or a field effect transistor 50 of metal-oxide semiconductor type as a typical example of plastic-encapsulated semiconductor devices mainly for high power application. MOSFET 50 comprises an electrically conducting, thermally radiating metallic support plate 1, a semiconducting chip or element 2 mounted on an upper surface 1a of support plate 1, three lead terminals 3 disposed around support plate 1, lead or bonding wires 9 and 25 for electrically connecting upper electrodes 12a and 12b of semiconducting chip 2 with lead terminals 3a and 3c in spaced relation to support plate 1, and a plastic-encapsulant 4 for hermetically sealing upper and side surfaces 1a and 1c of support plate 1, upper and side surfaces of semiconducting chip 2, lead wires 9 and 25 and each inner end 13 of lead terminals 3. Semiconducting chip 2 comprises a source electrode (one upper surface electrode) 12a and a gate electrode (the other upper surface electrode) 12b both formed on upper surface of chip 2, and a drain electrode (bottom surface electrode) 12c formed on the bottom surface of chip 2, and drain electrode 12c is secured on upper surface 1a of support plate 1 through an electrically conducting adhesive 7c such as solder or brazing filler metal. Whereas drain electrode 12c is electrically connected through support plate 1 to central lead terminal 3b integrally formed with support plate 1, source and gate electrodes 12a and 12b of chip 2 are electrically connected through lead wires 9 and 25 to respectively two lead terminals 3a and 3c away from support plate 1.

In preparing MOSFET 50 shown in FIG. 11, firstly a lead frame 22 is formed by pressing a metallic band made of copper, aluminum or these alloys into an elongated shape only a partial section of which is shown in FIG. 12. Lead frame 22 comprises openings 28 formed at regular intervals, a plurality of lead terminals 3 extending through opening 28 to one tie bar, a plurality of support plates 1 (only one shown) and a plurality of support leads 29 connecting support plates 1 and the other tie bar on the opposite side of lead terminals 3. Then, semiconducting chip 2 is mounted on upper surface 1a of support plate 1 through electrically conducting adhesive 7c by means of well-known die bonder. Subsequently, a well-known wire-bonding technique is used to electrically connect source and gate electrodes 12a and 12b on semiconducting chip 2 to lead terminals 3a and 3c through lead wires 9 and 25. After that, as shown in FIG. 13, lead frame 22 is attached between upper and lower mold halves 8a and 8b of a mold which are incorporated to define a cavity 18 for accommodating support plate 1. In this condition, thermo-setting resin melt 24 such as fluid epoxy resin is injected under pressure into cavity 18 from a runner through a gate to form plastic-encapsulant 4 while heating. Then, plastic-molded lead frame 22 is extracted from mold and unnecessary portions such as support leads 29 are removed from lead frame 22 to finish MOSFET 50 shown in FIG. 11.

During operation of MOSFET 50 shown in FIG. 11, it produces heat which can be released outside through support plate 1 to prevent overheat of semiconducting chip 2. In another aspect, the bottom surface 1b of support plate 1 can be exposed from plastic-encapsulant 4 which is molded while bottom surface 1b of support plate 1 is in close contact to lower mold half 8b within cavity 18 during the plastic molding process. Thus, heat transferred to support plate 1 can be preferably dissipated outside from bottom surface 1b of support plate 1 to improve the radiating property of MOSFET 50. However, a better characteristics in heat discharge has been required for plastic-encapsulated semiconductor devices with higher power capacity.

The following Patent Document 1 discloses a plastic-encapsulated semiconductor device and manufacture thereof, and this device comprises an electrically conducting and thermally radiating support plate, a semiconducting chip secured on an upper surface of support plate, a radiating plate secured on an upper surface of semiconducting chip, three lead terminals disposed around support plate, and a plastic-encapsulant for hermetically sealing upper and side surfaces of support plate, side surface of semiconducting chip, side and bottom surfaces of radiator and each one end of lead terminals. Plastic-encapsulated semiconductor device of Patent Document 1 can improve heat radiating property because heat emitted from semiconducting chip can be discharged through radiator outside of plastic-encapsulant as well as through support plate. Manufacture of preparing plastic-encapsulated semiconductor device of Patent Document 1, utilizes a pair of heat-radiating and compressible insulating sheets, one sheet being disposed between upper mold half and radiating plate and the other being disposed between lower mold half and support plate to prevent damage to semiconducting chip by clamping force on upper and lower mold halves during a transfer molding process for forming plastic-encapsulant.

Patent Document 2 as below discloses a plastic-encapsulated semiconductor device provided with a radiator integrally formed with a lead terminal so that the radiator performs two functions as an upper electrode of a semiconducting element and a heat sink or cooler.

[Patent Document 1] Japanese Patent Disclosure No. 2002-324816 (FIG. 1)

[Patent Document 2] Japanese Patent Disclosure No. 2005-218248 (FIG. 1(b))

### PROBLEM TO BE SOLVED BY INVENTION

Both of Patent Documents 1 and 2 utilize a molding process of forming, in a cavity of mold, plastic-encapsulant on a lead frame with a radiator already adhered on an upper surface of a semiconducting chip upon making the plastic-encapsulated semiconductor device which therefore has the radiator embedded and retained in the formed plastic-encapsulant. Accordingly, when another radiator of different shape is used, shape and size of the cavity in mold should simultaneously be changed thereby increasing the cost for manufacture. In this case, use of the same mold disadvantageously limits shape and size of radiator and bars adoption of an appropriate thermal capacity in radiator. In another aspect, Patent Document 2 teaches a radiator with an integrally formed lead terminal which requires change in a cavity shape of mold and wastes the current forming mold and lead frames.

Accordingly, an object of the present invention is to provide a plastic-encapsulated semiconductor device and its manufacture wherein the device has an exposed radiator at the top for variable heat capacity of the radiator as required. Another object of the present invention is to provide a plastic-encapsulated semiconductor device and its manufacture wherein the device has an exposed radiator at the top and may be made up by means of current mold and lead frame.

### MEANS FOR SOLVING THE PROBLEM

The plastic-encapsulated semiconductor device according to the present invention comprises an electrically conducting and thermally radiating support plate (1), a semiconducting element (2) secured on an upper surface (1a) of support plate (1), a plurality of lead terminals (3) disposed around support plate (1), a plastic-encapsulant (4) for hermetically sealing at least one upper surface (1a) of support plate (1), semiconducting element (2) and each inner end of lead terminals (3) and an electrically conducting radiator (5) exposed outside. Plastic-encapsulant (4) is formed with notches (14) which expose outside at least one upper electrode (12a) of semiconducting element (2) and an inner end (13) of at least one lead terminal (3a). Radiator (5) comprises a main radiator body (16) disposed on an upper surface (4a) of plastic-encapsulant (4) and connectors (16) located in corresponding notches (14) of plastic-encapsulant (4) for electrically connecting radiator body (16) with an upper electrode (12a) of semiconducting element (2) and with a lead terminal (3a). Radiator (5) provides a current path of its large section area, high mechanical strength and big current capacity in collaboration with connectors (16) and at the same time, it provides a heat sink or emitter of large thermal capacity or volume. Accordingly, heavy operating current can be sent to semiconducting element (2) through support plate (1) and radiator (5) and simultaneously a sufficient amount of heat produced during operation of semiconducting element (2) can be released in two directions through support plate (1) and radiator (5) both of which sandwich semiconducting element (2). Thus, the arrangement can increase operating current capacity and provide high-power semiconductor devices without deterioration in electric property of semiconducting element (2). In this case, a main radiator body (16) of different shape may be disposed on upper surface (4a) of plastic-encapsulant (4) as necessary to optionally change thermal capacity of radiator (5) without exchange of a mold for forming plastic-encapsulant (4). In addition, radiator (5) can offer a current path through one of connectors (16) to lead terminal (3a) making use of current lead frames without any modification to shape of plural outer leads (3).

The manufacture of the plastic-encapsulated semiconductor device comprises the steps of: mounting a semiconducting element (2) on an upper surface (1a) of an electrically conducting and thermally radiating support plate (1) in a lead frame (22), forming a plastic-encapsulant (4) for hermetically sealing at least one surface (1) of support plate (1), semiconducting element (2) and each inner end (13) of plural lead terminals (3) disposed around support plate (1), the plastic-encapsulant (4) being formed with notches (14) for exposing outside at least one upper electrode (12) of semiconducting element (2) and at least one inner end (13) of lead terminals (3), and providing on plastic-encapsulant (4) an electrically conducting radiator (5) a portion of which is exposed outside, the radiator (5) having a main radiator body (16) disposed on an upper surface (4a) of plastic-encapsulant (4) and connections (16) deployed in corresponding notches (14) of plastic-encapsulant (4) for electrically connecting main radiator body (16) with an upper electrode (12a) of semiconducting element (2) and with a lead terminal (3a). After formation of plastic-encapsulant (4) with notches (14), radiator (5) can be mounted on plastic-encapsulant (4) while main radiator body (16) is disposed on upper surface (4a) of plastic-encapsulant (4). At the same time, connections (16) are inserted into notches (14) of plastic-encapsulant (4) to electrically connect main radiator body (16) with an upper electrode (12a) of semiconducting element (2) and with a lead terminal (3a). Thus, the plastic-encapsulated semiconductor device can adopt radiators (5) of different shape independently of cavity shape or size in mold for forming plastic-encapsulant (4).

### EFFECT OF INVENTION

The present invention can realize a plastic-encapsulated semiconductor device of higher or better thermal radiation characteristics made at an inexpensive cost making use of current mold, current lead frame and optionally a radiator of same or different size and shape to be electrically connected to an upper electrode and lead terminal.

### BRIEF DESCRIPTION OF THE DRAWINGS

FIG. 1 A sectional view indicating an embodiment of the plastic-encapsulated semiconductor device according to the present invention;

FIG. 2 A perspective view of the device shown in FIG. 1;

FIG. 3 A perspective view of a lead frame used in the device shown in FIG. 1;

FIG. 4 A sectional view of a mold for forming a plastic-encapsulant in the device shown in FIG. 1;

FIG. 5 A perspective view showing a process for attaching a radiator to the plastic-encapsulant shown in FIG. 4;

FIG. 6 A sectional view of the lead frame shown in FIG. 5 with a gap between each of connections and each of notches in the plastic-encapsulant;

FIG. 7 A sectional view of the lead frame in the combined condition of the plastic-encapsulant and radiator;

FIG. 8 A perspective view of a different embodiment varied from that shown in FIG. 1;

FIG. 9 A perspective view of another embodiment with an L-shaped main radiator body of radiator;

FIG. 10 A sectional view of still another embodiment having connections of different material from that of a main radiator body in radiator;

FIG. 11 A perspective view of a prior art plastic-encapsulated semiconductor device;

FIG. 12 A plan view of the device shown in FIG. 11; and

FIG. 13 A sectional view of a mold for forming a plastic-encapsulant in the device shown in FIG. 11.

### EXPLANATION OF SYMBOLS

(1) . . . A support plate, (2) . . . A semiconducting chip (A semiconducting element), (3a, 3b, 3c) . . . Lead terminals, (4) . . . A plastic-encapsulant, (5) . . . A radiator, (7a, 7b, 7c) . . . Electrically conducting adhesive, (8a) . . . An upper mold half (A forming mold), (8b) . . . A lower mold half (A forming mold), (12a) . . . A source electrode (One upper electrode), (12b) . . . A gate electrode (The other upper electrode), (12c) . . . A drain electrode (A bottom electrode), (14) Notches, (14a) . . . An electrode notch, (14b) . . . A terminal notch, (14c) . . . A connection notch, (16) . . . A main radiator body, (16) . . . Connections, (17) . . . A lid, (18) . . . A cavity.

### BEST MODE FOR CARRYING OUT THE INVENTION

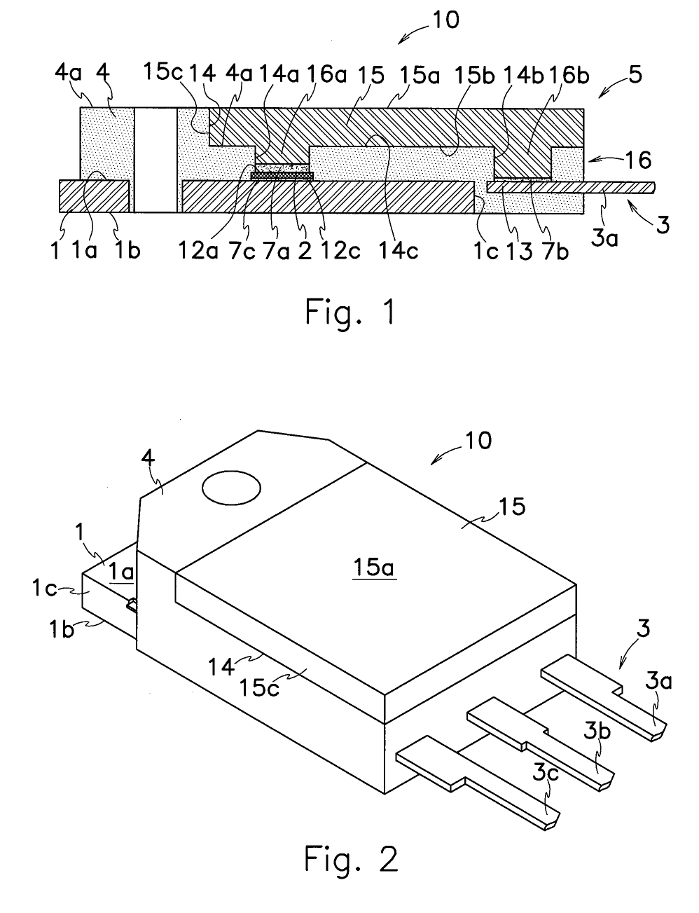

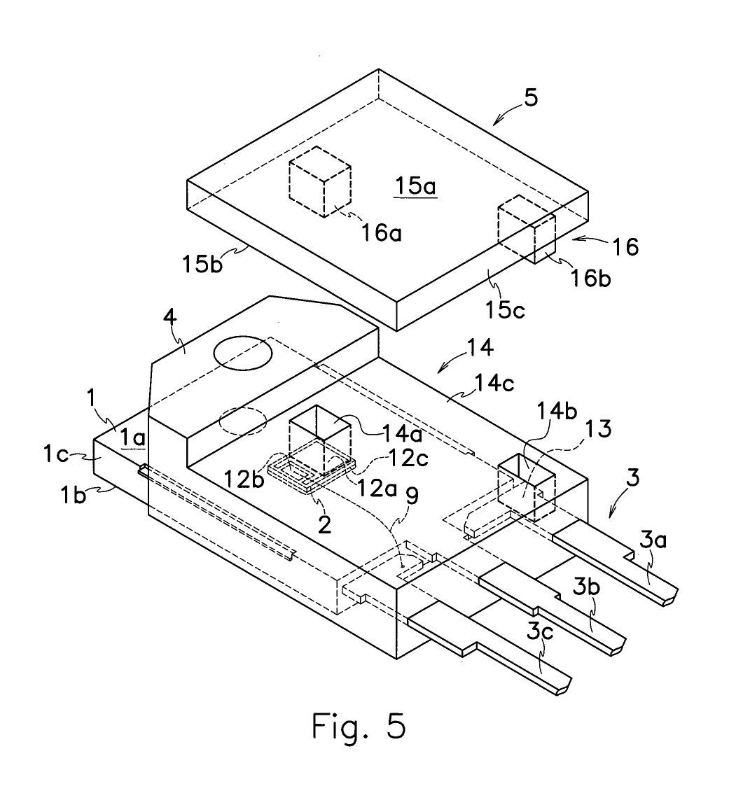

Embodiments of the present invention are described hereinafter with reference to FIGS. 1 to 10 wherein the plastic-encapsulated semiconductor device and its manufacture according to the present invention are applied to a MOSFET 10 and its manufacture. Same symbols as those in FIGS. 11 to 13 are applied to similar or same portions in FIGS. 1 to 10, and their explanation is omitted.

As shown in FIG. 1, the MOSFET 10 of this embodiment comprises a support plate 1, a semiconducting chip 2 mounted on support plate 1, and a plastic-encapsulant 4 and an electrically conducting and thermally diffusing radiator 5 exposed outside and mounted on plastic-encapsulant 4. Formed with notches 14 for exposing outside a source electrode (one upper electrode) 12a on an upper surface of semiconducting chip 2 and an inner end 13 of lead terminal 3a is plastic-encapsulant 4 which hermetically seals or covers upper and side surfaces 1a and 1c of support plate 1, side surfaces and peripheral upper surface of semiconducting chip 2, a lead wire 9 and each inner end of lead terminals 3. Lead wire 9 is a single fine metallic strand that electrically connects a gate electrode 12b of semiconducting chip 2 with an inner end of lead terminal 3c. Notches 14 in plastic-encapsulant 4 include a vertical electrode notch 14a of cylindrical or prismatic column shape upwardly extending from an upper surface 1a of support plate 1 over a source electrode 12a on upper surface of semiconducting chip 2, a vertical terminal notch 14b of cylindrical or prismatic column shape upwardly extending from an upper surface of inner end 13 of lead terminal 3a in spaced relation to support plate 1, and a connection notch 14c connecting electrode and terminal notches 14a and 14b. Formed in plastic-encapsulant 4 is generally flat connection notch 14c shallower than each bottom of electrode and terminal notches 14a and 14b but lower than an upper surface 4a of plastic-encapsulant 4. Electrode and terminal notches 14a and 14b vertically extend from connection notch 14c to respectively semiconducting chip 2 and lead terminal 3a to expose source electrode 12a of semiconducting chip 2 and inner end 13 of lead terminal 3a through electrode and terminal notches 14a and 14b unless they are not covered with radiator 5 while upper surface 1a of support plate 1 and each inner end of lead terminals 3b and 3c other than lead terminal 3a are hermetically covered with plastic-encapsulant 4. Electrode notch 14a is formed in coaxial relation to source electrode 12a of semiconducting chip 2 to expose source electrode 12a outside through electrode notch 14a, but outer periphery of source electrode 12a is covered with plastic-encapsulant 4 around electrode notch 14a.

As illustrated in FIG. 2, mounted on plastic-encapsulant 4 is radiator 5 that is formed in unison by press working of a metallic material having its high coefficient of thermal conductivity such as copper or aluminum. Radiator 5 has a main radiator body 15 positioned on upper surface 4a of flat connection notch 14c in plastic-encapsulant 4, and connectors 16 integrally formed with main body 15 to downwardly extend from main body 15. Connectors 16 have electrode and terminal connectors 16a and 16b; electrode connector 16a is fit in electrode notch 14a of plastic-encapsulant 4 to electrically connect source electrode 12a of semiconducting chip 2 with main body 15 through connector 16a; and terminal connector 16b is fit in terminal notch 14b of plastic-encapsulant 4 to electrically connect main body 15 with lead terminal 3a through connector 16b. To this end, electrode connector 16a in electrode notch 14a is bonded to source electrode 12a of semiconducting chip 2 through electrically conducting adhesive such as solder or blazing filler metal, and similarly, terminal connector 16b in terminal notch 14b is bonded to inner end 13 of lead terminal 3a through electrically conducting adhesive such as solder or blazing filler metal. In this case, main body 15 may be in contact to upper surface 4a of plastic-encapsulant 4 to electrically insulate radiator 5 from lead wire 9 and support plate 1 by intervening plastic-encapsulant 4 in order to protect radiator 5 against short circuit with gate electrode 12 and gate (bottom) electrode 12c of semiconducting chip 2. Electrically conducting adhesive 7a in electrode notch 14a has enough thickness to provide a shock eliminator by adhesive 7a for alleviating external force applied to electrode connector 16a of radiator 5 and transmitted onto semiconducting chip 2.

As shown in FIGS. 1 and 2, main body 15 may be formed into a generally plate shape having its substantially same thickness as but its smaller flat surface area than that of support plate 1. Bottom surface 15b of main body 15 is in close contact to upper surface 4a of plastic-encapsulant 4 with bare upper and three side surfaces 16a and 15c of main body that provide heat radiating surfaces unsealed from plastic-encapsulant 4 to improve the heat discharge characteristics. However, the present invention also contemplates another embodiment of a plastic-encapsulated semiconductor device wherein only an upper surface 16a of main body 15 is open for heat radiating while all side surfaces 15c of main body 15 are entirely covered with plastic-encapsulant 4. MOSFET 10 may have a main radiator body 15 of the flat surface area larger than that of support plate 1.

MOSFET 10 shown in FIGS. 1 and 2 has electrode and terminal connections 16a and 16b for supporting radiator 5 over support plate 1 on two locations that ensure more stable maintenance of radiator 5 over support plate 1 than the structure shown in Patent Document 1 or 2. External force or shock transmitted through radiator 5 can be dispersed on semiconducting chip 2 and lead terminal 3a to preferably prevent mechanical damage to semiconducting chip 2.

In this embodiment, radiator 5 provides a current path of its large section area, high mechanical strength and big current capacity and at the same time, provides a heat sink or emitter of large thermal capacity because radiator 5 has main body 15 and connections 16 which are incorporated together to electrically connect source electrode 12a of semiconductor ship 2 with lead terminal 3a. Accordingly, heavy operating current can be sent to semiconducting element 2 through support plate 1 and radiator 5 and simultaneously a sufficient amount of heat produced during operation of semiconducting element 2 can be released in two directions through support plate 1 and radiator 5 both of which sandwich semiconducting element 2. Thus, the arrangement can increase operating current capacity and provide high-power semiconductor devices without deterioration in electric property of semiconducting element 2. In this case, main body 15 of different shape or size may be selected and disposed on upper surface 4a of plastic-encapsulant 4 as necessary to optionally change thermal capacity of radiator 5 without exchange of a mold for forming plastic-encapsulant 4. In addition, radiator 5 can offer a current path through one of connectors 16 to lead terminal 3a making use of current lead frames 22 without any modification to shape of plural outer leads 3. Main body 15 connects electrode and terminal connections 16a and 16b and further horizontally extends beyond electrode and terminal connections 16a and 16b along upper surface 4a of plastic-encapsulant 4 to form a cover of widened flat area like a brim over upper surface 4a for enhancement in heat discharge characteristics of radiator 5.

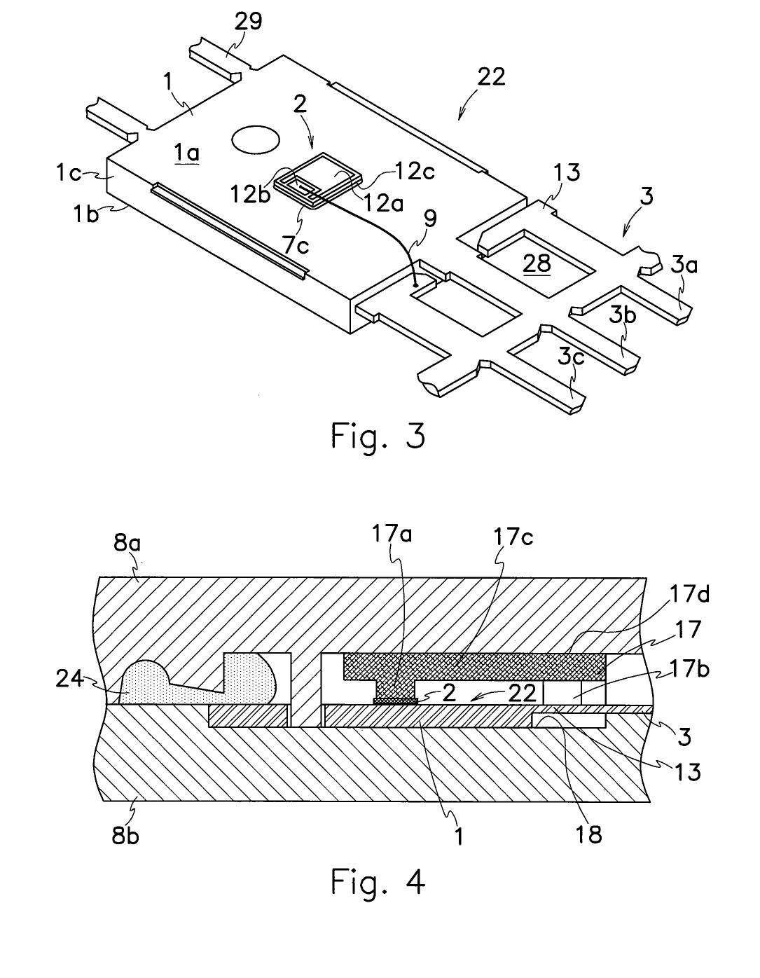

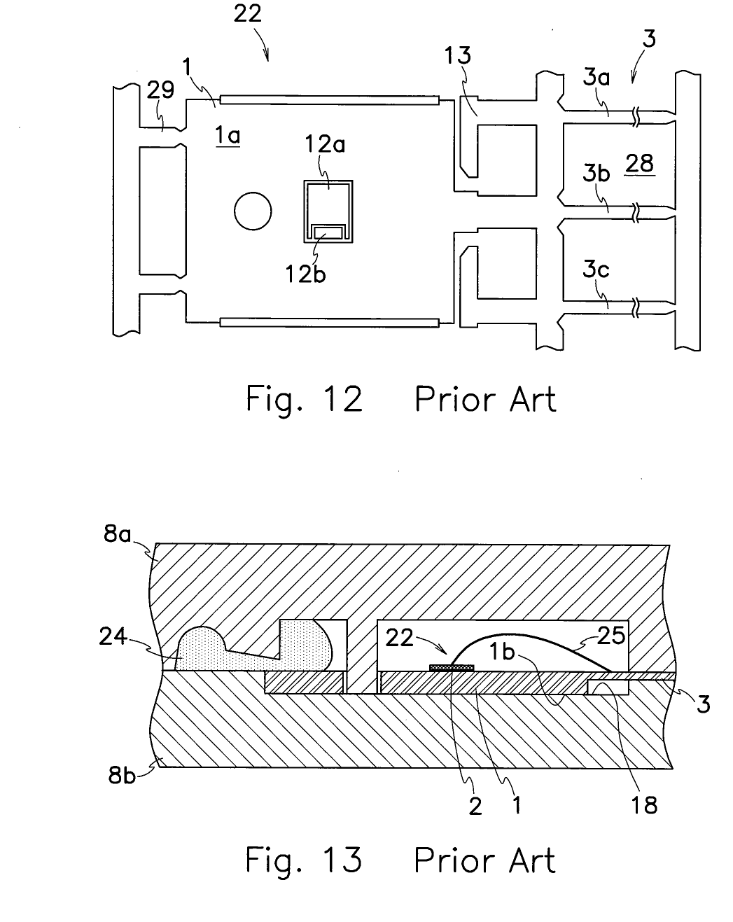

In making MOSFET 10 shown in FIG. 1, a lead frame 22 is prepared which may be of the same type as current or existing one as shown in FIG. 12. Then, as shown in FIG. 3, a semiconducting chip 2 is mounted and adhered on upper surface 1a of support plate 1 through electrically conducting adhesive 7c, and only gate electrode 12b of semiconducting chip 2 is electrically connected to lead terminal 3c through lead wire 9 one end of which being connected to gate electrode 12b of semiconducting chip 2 and the other end being connected to inner end of lead terminal 3c. Here, lead frame 22 is attached between upper and lower mold halves 8a and 8b of forming mold as shown in FIG. 4 with a lid 17 so that support plate 1 and lid 17 can be positioned within mold cavity 18 to cover a part of source electrode 12a on semiconducting chip 2 and a part of inner end 13 on support plate 1 of lead terminal 3a except upper surface 1a of support plate 1. Lid 17 may be disposed in mold 8a and 8b before or after lead frame 22 is attached in mold 8a and 8b. Lid 17 is formed of heat resistible material such as silicone resin which also can perform a buffer function when upper and lower mold halves 8a and 8b clamp lead frame 22 and lid 17. Lid 17 comprises a lid body 17c and electrode and terminal lids 17a and 17b both integrally formed with lid body 17c so that electrode and terminal lids 17a and 17b extend downwardly from lid body 17c. Lid 17 has a generally similar shape as that of radiator 5 with a planar or flat upper surface 17d of lid body 17c which is brought into close and tight contact to inner surface of upper mold half 8a when upper and lower mold halves 8a and 8b are clamped. When a transfer molding technique is used to inject thermosetting resin melt under pressure into cavity 18, liquid resin flows and is tightly filled around upper and side surfaces 1a and 1c of support plate 1, upper and side surfaces of semiconducting chip 2 uncovered with electrode lid 17a, lead wire 9 and inner end 13 of lead terminal 3 to form plastic-encapsulant 4 by heating the filled resin.

After that, lead frame 22 is extracted from forming mold with released upper and lower mold halves 8a and 8b, and lid 17 is easily removed from plastic-encapsulant 4 because lid 17 is not molded in plastic-encapsulant 4 which comprises electrode, terminal and connection notches 14a, 14b and 14c formed after removal of electrode, terminal and connection lids 17a, 17b and 17c. Then, each chip of electrically conducting adhesives 7a and 7b is placed in electrode and terminal notches 14a and 14b, and radiator 5 is placed on notches 14 of plastic-encapsulant 4 so that connectors 16 of radiator 5 can be just fit in connection notch 14c because connectors 16, 16a and 16b have complementary shapes to those of notches 14, 14a and 14b of plastic-encapsulant 4. Subsequently, radiator 5 is heated to melt or fuse chips of electrically conducting adhesives 7a and 7b and thereby electrically connect source electrode 12a of semiconducting chip 2 with lead terminal 3a through adhesives 7a and 7b and radiator 5 in the condition of bottom surface 15b of main body 15 directly abutting or being in close contact to upper surface 4a of connection notch 14c in plastic-encapsulant 4. Adhesives 7a and 7b serve to strongly and undetachably bond radiator 5 on source electrode 12a of semiconducting chip 2 and lead terminal 3a to firmly prevent radiator 5 from being separated from support plate 1 and plastic-encapsulant 4. Accordingly, this arrangement can adopt radiator 5 made of highly heat-discharging metallic material of low or less adhesivity to plastic-encapsulant 4. Finally, unnecessary portions are cleaned up to finish MOSFET 10 shown in FIG. 1. Pursuant to this embodiment, manufacture of MOSFET 10 can utilize an existing or current forming mold 8a and 8b or the same type thereof.

The present invention contemplates another embodiment that notches 14 can be formed later in formed plastic-encapsulant 4. In a further aspect, before molding of plastic-encapsulant 4 and before or after bonding of lead wire 9 between gate electrode 12b and lead terminal 3c, an electrically conducting extension but not shown in the drawings is attached on source electrode 12a of semiconductor chip 2 to provide a substantially extended source electrode 12a, and this extension may be formed of for example electrically conducting resin to protect source electrode 12a from molding of plastic-encapsulant 4. Then, support plate 1 of lead frame 22 is arranged in cavity 18 of forming mold 8a and 8b without lid 17. Resin melt 24 is injected under pressure into cavity 18 to form plastic-encapsulant 4 which hermetically seals upper and side surfaces 1a and 1c of support plate 1, respective upper and side surfaces of extension and semiconducting chip 2, lead wire 9 and inner end 13 of lead terminal 3. Afterward, electrode and terminal notches 14a and 14b are formed in molded plastic-encapsulant 4 by machine-working such as fine cutting. During machine-working, an upper portion of extension over semiconducting chip 2 is cut out by machine to bore or drill electrode notch 14a without damaging semiconducting chip 2. Then, similarly to the foregoing process, radiator 5 is attached on plastic-encapsulant 4 to produce MOSFET 10 as shown in FIG. 1.

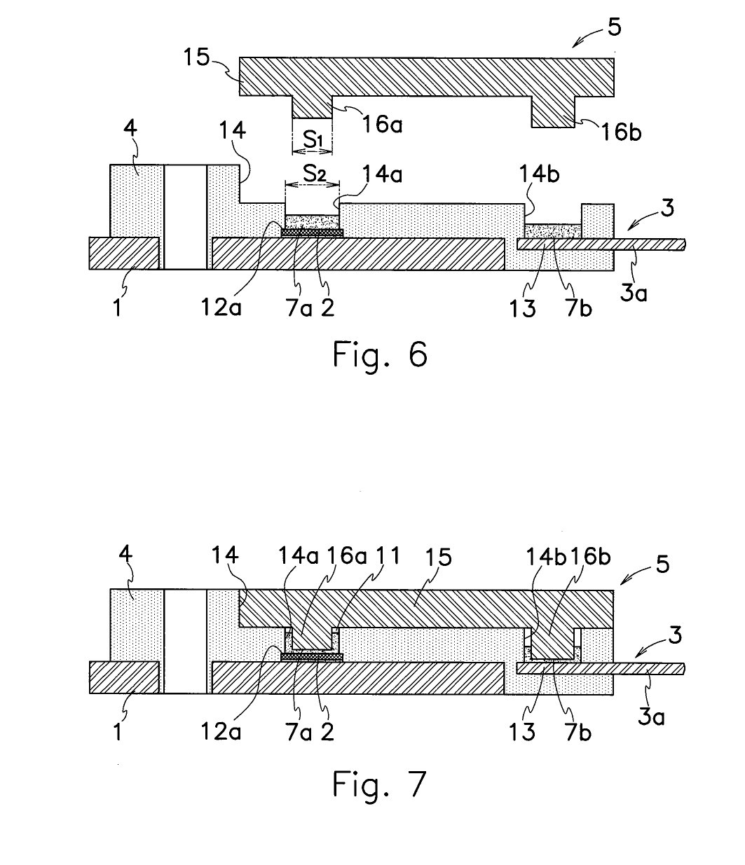

If bottom surface 15b of main body 15 is not in close contact to upper surface 4a of plastic-encapsulant 4 or any gap is formed between bottom surface 15b of main body 15 and upper surface 4a of plastic-encapsulant 4, completed plastic-encapsulated semiconductor device degrades reliability in quality of product because of reduction in heat discharge characteristics. Accordingly, high accuracy is required for each shape in radiator 5 and plastic-encapsulant 4 and volume or amount of used electrically conducting adhesives 7a, 7b and 7c. Otherwise, however, some resin may be filled in a gap which may be defined between radiator 5 and plastic-encapsulant 4 for their tight contact. Alternatively, alteration may be done on shape or size of radiator 5 and plastic-encapsulant 4 to surely bring bottom surface 15b of main body 15 into tight contact to upper surface 4a of plastic-encapsulant 4. As shown in FIG. 6, each planar section area S₁ of electrode and terminal connectors 16a and 16b of radiator 6 is formed smaller than that S₂ of notches 14 of plastic-encapsulant 4 to give clearances 11 between plastic-encapsulant 4 and each of electrode and terminal connections 16a and 16b as shown in FIG. 7. In this instance, radiator 5 is heated to melt electrically conducting adhesives 7a and 7b which then melt into liquid and flow into clearances 11 due to pressure of electrode and terminal connections 16a and 16b derived from their own and main body's weight to thereby cause bottom surface 15b of main body 15 to come into close contact with upper surface 4a of plastic-encapsulant 4. Also, each volume, amount or thickness of electrically conducting adhesives 7a and 7b may be increased to strongly bond between electrode connection 16a of radiator 5 and source electrode 12a of semiconducting chip 2 and between terminal connection 16b of radiator 5 and lead terminal 3a. Here, extra amount of melt adhesives 7a and 7b can flow and fill in clearances 11 which are formed by difference in planar section area between electrode connection 16a of radiator 5 and electrode notch 14a of plastic-encapsulant 4 and between terminal connection 16b and terminal notch 14b. In this case, each length of electrode and terminal connections 16a and 16b may be formed shorter than each depth of electrode and terminal notches 14a and 14b to bring bottom surface 15b of main body 15 into tight contact to upper surface 4a of plastic-encapsulant 4.

The above-mentioned method for producing MOSFET 10 enables a manufacturer or manufacturing equipment to select and attach radiator 5 of different, diverse or changed shape or size on upper surface 4a of previously molded plastic-encapsulant 4 regardless of shape or size of cavity in forming mold because radiator 5 can electrically connect source electrode 12a of semiconducting chip 2 with lead terminal 3a through main body 15 and connectors 16 in notches 14 of previously molded plastic-encapsulant 4.

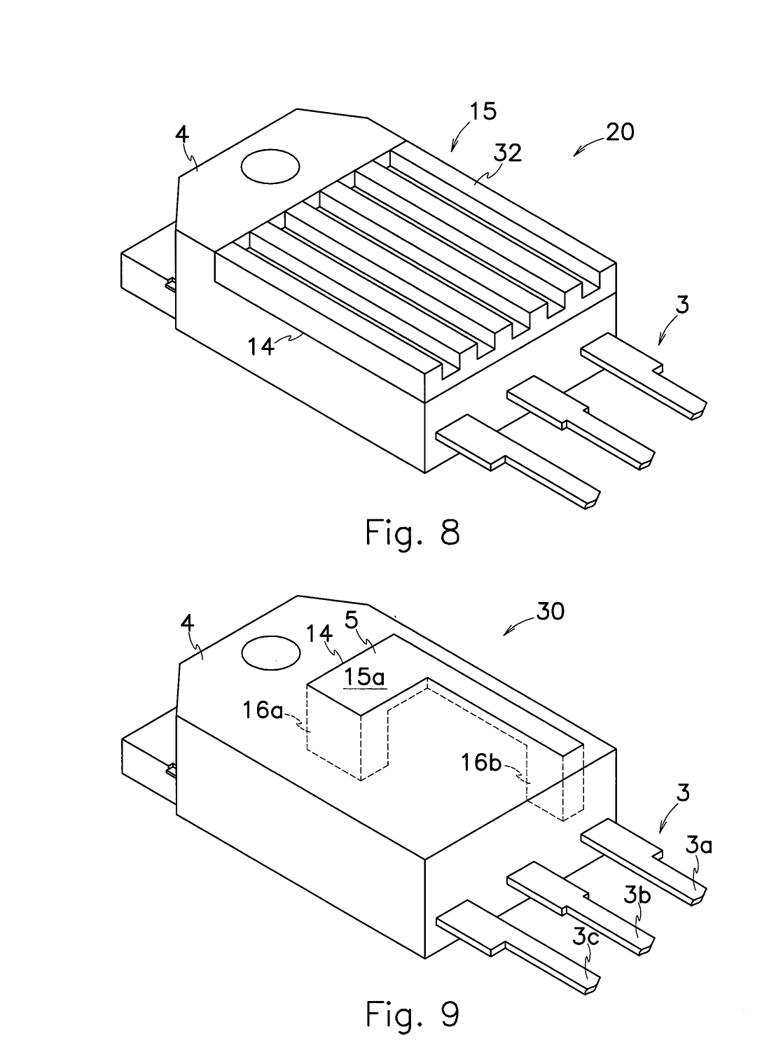

The foregoing embodiments of the plastic-encapsulated semiconductor device and its manufacture according to the present invention may be varied in various ways. MOSFET 10 shown in FIG. 2 is provided with main body 15 of flat upper surface 16a, however, a plurality of radiating fins 32 formed on an outer surface of main body 15 in MOSFET 20 shown in FIG. 8. Radiating fins 32 have increased outer surface areas for heat transfer with air to more improve radiation performance. Without limitation to corrugation shape like fins 32, the outer configuration of main body 15 can be changed to any shapes for example as mesh, dents or another suitable shape in response to required radiation property or appearance of radiator 5. Because plastic-encapsulant 4 is molded on lead frame 22 on ahead utilizing the previous transfer molding process, radiator 5 of different shape and size can be attached on formed plastic-encapsulant 4. In other words, so far as radiator 5 can be appropriately attached to plastic-encapsulant 4, a manufacturer or manufacturing equipment can freely select and adopt radiator 5 of any shape and size without restriction to mount it on plastic-encapsulant 4 in response to application. Of course, existing or current forming mold 8a and 8b or the same type thereof may be used to fabricate MOSFET 20 with finned (32) main body 15.

MOSFET 30 of the invention shown in FIG. 9 comprises an L-shaped main body 15 of radiator 5 mounted in a connection notch 14c of plastic-encapsulant 4 to expose outside upper surface 16a only of main body 15. In mounting radiator 5 in connection notch 14c, heated liquid metallic material such as solder or brazing filler can be poured in electrode, terminal and connection notches 14 of plastic-encapsulant 4, and then metallic material can be cooled to solidify it into radiator 5 formed integrally with main body 15 and connections 16. In this manufacture, first plastic-encapsulant 4 is molded on lead frame 22 making use of transfer molding process and then lead frame 22 is moved to another forming mold to pour liquid metallic material into notches 14 of plastic-encapsulant 4.

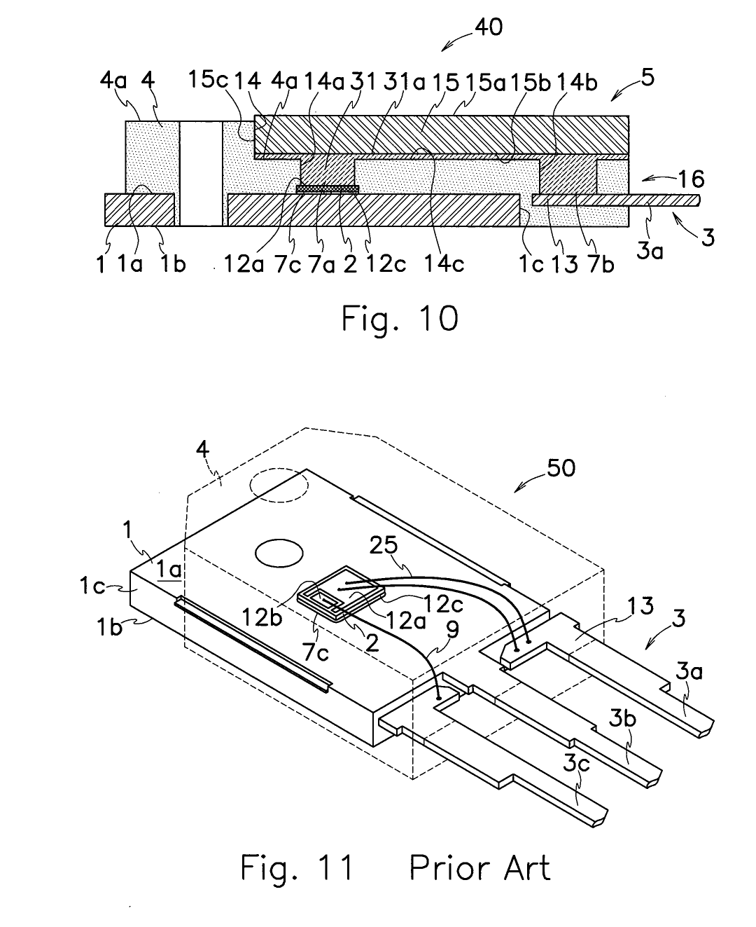

MOSFET 40 of the invention shown in FIG. 10 enables main body 15 and connections 16 to be formed of different materials. In this embodiment, to form radiator 5, firstly, connections 16 are made by putting electrically conducting and heat transmitting resin or metallic base material 31 in notches 14 of plastic-encapsulant 4 or filling notches 14 with liquid electrically conducting base material 31. Next, main body 15 of radiator 5 is located on base material 31 or over upper surface 4a of plastic-encapsulant 4, while main body 15 and connections 16 are bonded each other by adhesive property of connections or main body 15 or by heating or any other suitable means.

In the above shown embodiments, plastic-encapsulant 4 is molded in forming mold under the condition of bottom surface 1b of support plate 1 in close contact to lower mold half 8b of forming mold to expose outside bottom surface 1b of support plate 1 from plastic-encapsulant 4. Otherwise, a bottom plastic film of plastic-encapsulant 4 may be formed under bottom surface 1b of support plate 1 to provide a fully plastic-molded semiconductor device. As shown upper surface 5a of radiator 5 may be of a same level as upper surface 4a of plastic-encapsulant 4, however, without limitation thereto, upper surface 5a may be higher or lower than upper surface 4a of plastic-encapsulant 4. Additional or further radiator or radiators may be put or secured on upper surface 15a of main body 15. Not limited to MOSFET, the present invention is applicable to other plastic-encapsulated semiconductor devices such as transistors such as IGBT (Insulated Gate Bipolar Transistor) or thyristor (Silicon-Controlled Rectifier).

### APPLICABILITY OF INVENTION IN INDUSTRY

The present invention can preferably be applied to plastic-encapsulated semiconductor devices such as power transistors for use in power supplies or driving equipments that requires high heat radiating characteristics.

What is claimed are:

1. A plastic-encapsulated semiconductor device comprising: an electrically conducting and thermally radiating support plate,
a semiconducting element secured on an upper surface of the support plate,
a plurality of lead terminals disposed around the support plate,
a plastic-encapsulant for hermetically sealing at least one upper surface of the support plate, semiconducting element and each inner end of the lead terminals and
an electrically conducting radiator exposed outside,
wherein the plastic-encapsulant is formed with notches which expose outside at least one upper electrode of the semiconducting element and an inner end of at least one of the lead terminals,
the radiator comprises a main radiator body disposed on an upper surface of the plastic-encapsulant and connectors located in the corresponding notches of the plastic-encapsulant for electrically connecting the radiator body with an upper electrode of the semiconducting element and with a lead terminal.

2. The plastic-encapsulated semiconductor device of claim 1, wherein the main radiator body has its larger planar surface area than those of the connections to extend outwardly from the connections and spread on the upper surface of the plastic-encapsulant.

3. The plastic-encapsulated semiconductor device of claim 1, wherein the connectors of the radiator include electrode and terminal connectors both formed integrally with and extending from the main radiator body in parallel to and in the same direction each other,
the electrode connection is disposed in one of the notches to be bonded to the upper electrode of the semiconducting element through an electrically conducting adhesive,
the terminal connection is disposed in another one of the notches to be bonded to an inner end of the lead terminal through an electrically conducting adhesive, and
the main radiator body directly abuts on the upper surface of the plastic-encapsulant.

4. The plastic-encapsulated semiconductor device of claim 1, wherein the notches include an electrode notch for exposing outside the upper electrode of the semiconducting element, a terminal notch for exposing outside the inner end of the lead terminal and a connection notch for connecting the electrode and terminal notches, and
the main radiator body is disposed on the connection notch of the plastic-encapsulant.

5. The plastic-encapsulated semiconductor device of claim 1, wherein the main radiator body has a plurality of fins integrally formed on the outer surface thereof.

6. A method for producing a plastic-encapsulated semiconductor device, comprising the steps of: bonding a semiconducting element on an upper surface of an electrically conducting and thermally radiating support plate in a lead frame,
forming a plastic-encapsulant for hermetically sealing at least one surface of the support plate, semiconducting element and each inner end of the plural lead terminals disposed around the support plate, the plastic-encapsulant being formed with notches for exposing outside at least one upper electrode of the semiconducting element and at least one inner end of the lead terminals, and
providing on the plastic-encapsulant an electrically conducting and thermally radiating radiator at least a portion of which is exposed outside, the radiator having a main radiator body disposed on an upper surface of the plastic-encapsulant and connections deployed in the corresponding notches of the plastic-encapsulant to electrically connect the main radiator body with an upper electrode of the semiconducting element and a lead terminal.

7. The method of claim 6, wherein the process of forming the plastic-encapsulant comprises the steps of:
attaching the lead frame in a mold while the support plate is disposed in a cavity of the mold,
injecting resin melt into the cavity under pressure to form a plastic-encapsulant for hermetically sealing at least one upper surface of the support plate, semiconducting element and each inner end of the lead terminals,
extracting the lead frame with the plastic-molded support plate from the cavity, and
forming the notches in the plastic-encapsulant to expose outside the upper electrode of the semiconducting element and inner end of the lead terminal.

8. The method of claim 6, wherein the process of forming the plastic-encapsulant formed with the notches comprises the steps of:
disposing on the support plate a lid for covering at least one upper electrode of the semiconducting element and at least one inner end of the plural lead terminals arranged around the support plate,
attaching the lead frame to the forming mold while the support plate with the lid is placed in the cavity,
injecting resin melt into the cavity under pressure to form a plastic-encapsulant for hermetically sealing at least one upper surface of the support plate, an uncovered upper surface of the semiconducting element and inner end of the lead terminals,
retracting the lead frame with the plastic-molded support plate from the cavity, and
removing the lid from the plastic-encapsulant to reveal outside the notches of the plastic-encapsulant.

9. The method of claim 6, wherein the connections of the radiator comprises electrode and terminal connections formed integrally with the main radiator body to extend from the main radiator body in parallel to and in the same direction each other,
the process of providing the radiator comprises the steps of:
placing electrically conducting adhesives and electrode and terminal connections of the radiator in the notches of the radiator, and
heating the radiator to melt the adhesives and thereby bond the electrode and terminal connections of the radiator with respectively upper electrode of the semiconducting element and inner end of the lead terminal.

10. The method of claim 9, wherein each planar surface area of the electrode and terminal connections in the radiator is smaller than that of the corresponding notch of the plastic-encapsulant to define clearances between each of the electrode and terminal connections and the plastic-encapsulant,
the process of heating the radiator comprises a step of melting the adhesives into liquid by heating to cause the adhesives to flow into the clearances due to pressure of the electrode and terminal connections derived from their own and main body's weight to thereby cause the bottom surface of the main radiator body to come into close contact with the upper surface of the plastic-encapsulant so that the electrode and terminal connections of the radiator are connected with respectively the upper electrode of the semiconducting element and inner end of the lead terminal.

11. The method of claim 6, wherein the notches of the plastic-encapsulant comprises an electrode notch for exposing outside the upper electrode of the semiconducting element, a terminal notch for exposing outside the inner end of the lead terminal, and a connection notch for connecting the electrode and terminal notches,
the process of providing the radiator comprises filling heated liquid metallic material in the electrode, terminal and connection notches of the plastic-encapsulant and cooling the metallic material to form the radiator integrally with the main radiator body and connections.

12. The method of claim 6, wherein the process of providing the radiator comprises the steps of:
inserting electrically conducting materials or filling electrically conducting liquid materials in the notches of the plastic-encapsulant, and
disposing the main radiator body on the upper surface of the plastic-encapsulant or the upper surface of the electrically conducting material to bond the main radiator body to the connections.
